(19) United States
(12) Patent Application Publication
(10) Pub. No.: US 2007/0161183 A1
(43) Pub. Date: Jul. 12, 2007

(54) Method for fabricating semiconductor device

(75) Inventor: Chang-Youn Hwang, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/601,261

(22) Filed: Nov. 17, 2006

(30) Foreign Application Priority Data
Jan. 6, 2006 (KR) 2006-0001836

(51) Int. Cl. H01L 21/8242

(52) U.S. Cl. 438/253

(57) ABSTRACT

A method for fabricating a semiconductor device includes forming a plurality of bit line patterns, each bit line pattern having a double-layer hard mask including a nitride-based layer and an amorphous carbon-based layer, forming a planarized insulation layer filled between the bit line patterns, the planarized insulation layer flush with the nitride-based layer, forming line type storage node contact masks over predetermined portions of the planarized insulation layer, etching the planarized insulation layer to form storage node contact holes each having a top portion which is wider than a bottom portion, forming storage node contact spacers in a double layer structure on sidewalls of the storage node contact holes, and forming storage node contacts filling the storage node contact holes.

### FIELD OF THE INVENTION

The present invention relates to a method for fabricating a semiconductor device, and more particularly, to a method for fabricating a semiconductor device including a storage node contact.

### DESCRIPTION OF RELATED ARTS

As semiconductor devices have become more highly integrated, a storage node contact under 80 nm has been formed in a trench type using ArF photoresist. After performing a plug polysilicon deposition and isolation during a trench type storage node contact formation, the size of a top open surface of the storage node contact remains small, resulting in a lack of overlay margin with respect to a subsequent storage node. Thus, it is generally required to form a pad polysilicon.

The ArF photoresist used in the trench type storage node contact formation generally requires using expensive devices, and thus, mass-producibility deteriorates due to increased maintenance expenses.

FIG. 1A illustrates a micrographic view of typical bit lines lacking sufficient top surfaces. FIG. 1B illustrates a micrographic view of nitride-based bit line hard mask layers damaged during a subsequent self-aligned contact (SAC) etching process due to the lack of sufficient top surfaces. FIG. 1C illustrates a micrographic view of a SAC fail caused by a lack of bit line spacer thickness during a typical storage node contact formation process.

Referring to FIG. 1A, a polymer barrier may not form during a storage node contact etching process due to the decreased size of the bit lines. The bit lines have decreased in size due to device micronization. Consequently, a SAC etching may not be performed, resulting in a SAC fail between the storage node contact and a subsequent storage node contact. That is, a SAC etching characteristic generally provided by the polymer barrier is often not secured because of the lack of sufficient top surfaces of the bit lines. Thus, a loss of the nitride-based bit line hard mask layers may occur, resulting in short-circuits between the bit lines and the storage node contacts (refer to FIG. 1B).

Referring to FIG. 1C, bit line spacers having an asymmetric thickness are formed due to the usage of an oxide-based spacer material. A bit line spacer denoted with a circle has a smaller thickness than another bit line spacer formed on the other side of a bit line. The bit line spacer having the asymmetric thickness results in a SAC fail where short-circuits are generated in weak points between bit lines and storage node contacts. That is, a desired thickness of the bit line spacer may not be obtained due to the asymmetry. The asymmetry results because nitride-based storage node contact spacers are formed before storage node contact holes are formed.

### SUMMARY OF THE INVENTION

It is, therefore, an object of the present invention to provide a method for fabricating a semiconductor device, which can improve a top profile of bit lines to secure a self-aligned contact (SAC) etching characteristic, improve asymmetry of bit line spacers, minimize loss of a nitride-based bit line hard mask layer during a spacer etching process, and simplify processes.

In accordance with an aspect of the present invention, there is provided a method for fabricating a semiconductor device, including: forming a plurality of bit line patterns, each bit line pattern having a double-layer hard mask including a nitride-based layer and an amorphous carbon-based layer; forming a planarized insulation layer filled between the bit line patterns, the planarized insulation layer flush with the nitride-based layer; forming line type storage node contact masks over predetermined portions of the planarized insulation layer; etching the planarized insulation layer to form storage node contact holes each having a top portion which is wider than a bottom portion; forming storage node contact spacers in a double layer structure on sidewalls of the storage node contact holes; and forming storage node contacts filling the storage node contact holes.

### BRIEF DESCRIPTION OF THE DRAWINGS

The above and other objects and features of the present invention will become better understood with respect to the following description of the exemplary embodiments given in conjunction with the accompanying drawings, in which:

FIG. 1A illustrates a micrographic view of typical bit lines lacking sufficient top surface areas;

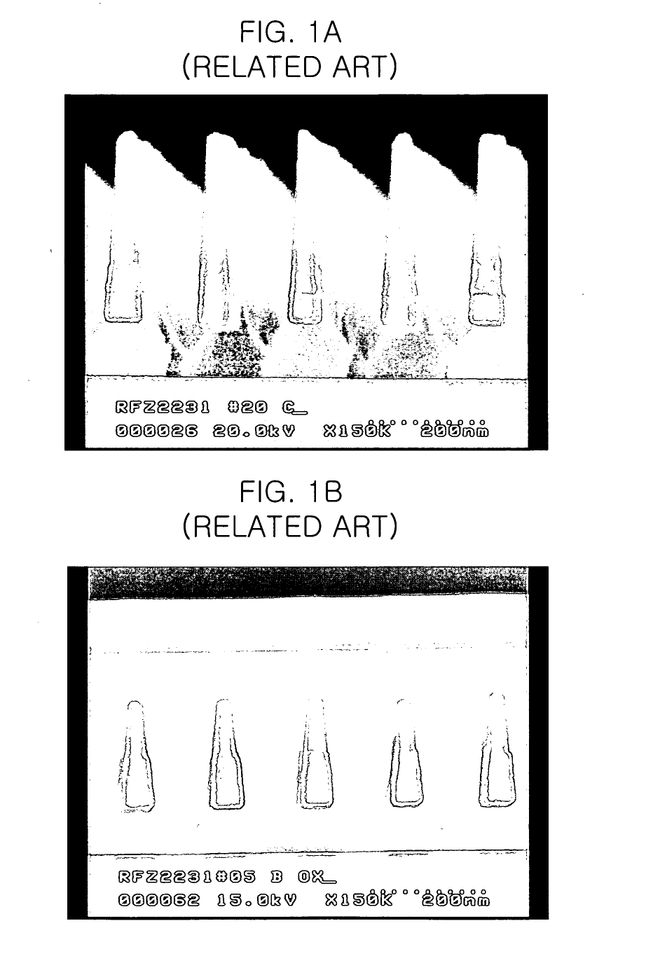

FIG. 1B illustrates a micrographic view of typical nitride-based bit line hard mask layers damaged during a self-aligned contact (SAC) etching process due to a lack of sufficient top surface areas;

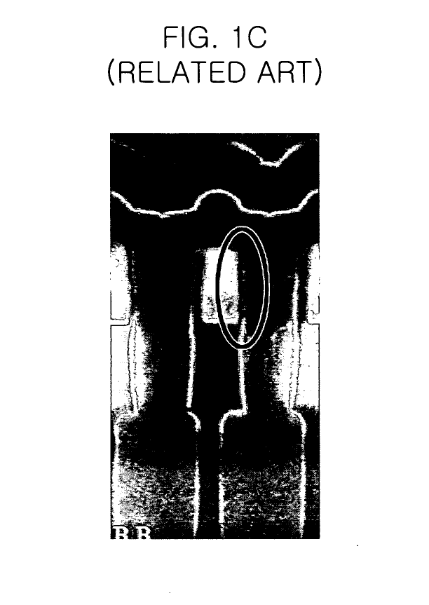

FIG. 1C illustrates a micrographic view of a SAC fail caused by a lack of bit line spacer thickness during a typical storage node contact formation process;

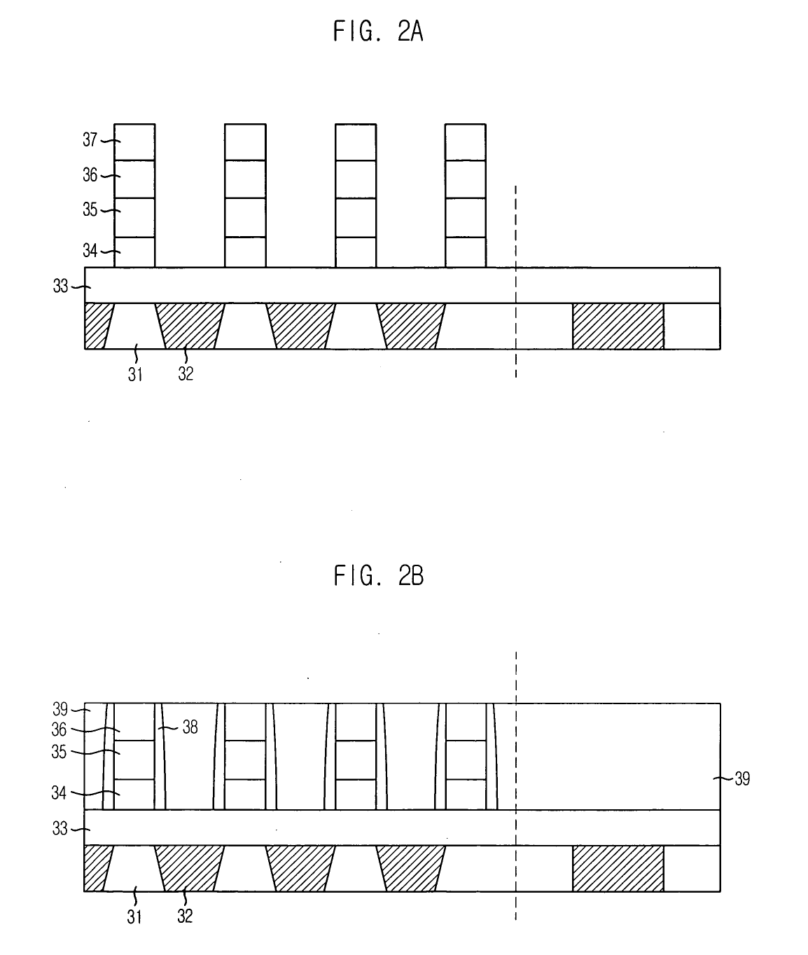

FIGS. 2A to 2E illustrate cross-sectional views to describe a method for fabricating a semiconductor device in accordance with an exemplary embodiment of the present invention;

FIG. 3 illustrates a micrographic view of bit line patterns including nitride-based bit line hard mask layers with a minimized loss due to a usage of amorphous carbon-based bit line hard mask layers;

FIG. 4 illustrates a micrographic view of bit line patterns with a reduced SAC fail due to an improved bit line spacer thickness in accordance with an exemplary embodiment of this invention; and

FIG. 5 illustrates a micrographic view of a bit line pattern including a nitride-based bit line hard mask layer wherein a loss of the bit line hard mask layer is prevented by applying a buffer oxide layer.

### DETAILED DESCRIPTION OF THE INVENTION

A method for fabricating a semiconductor device in accordance with exemplary embodiments of the present invention will be described in detail with reference to the accompanying drawings.

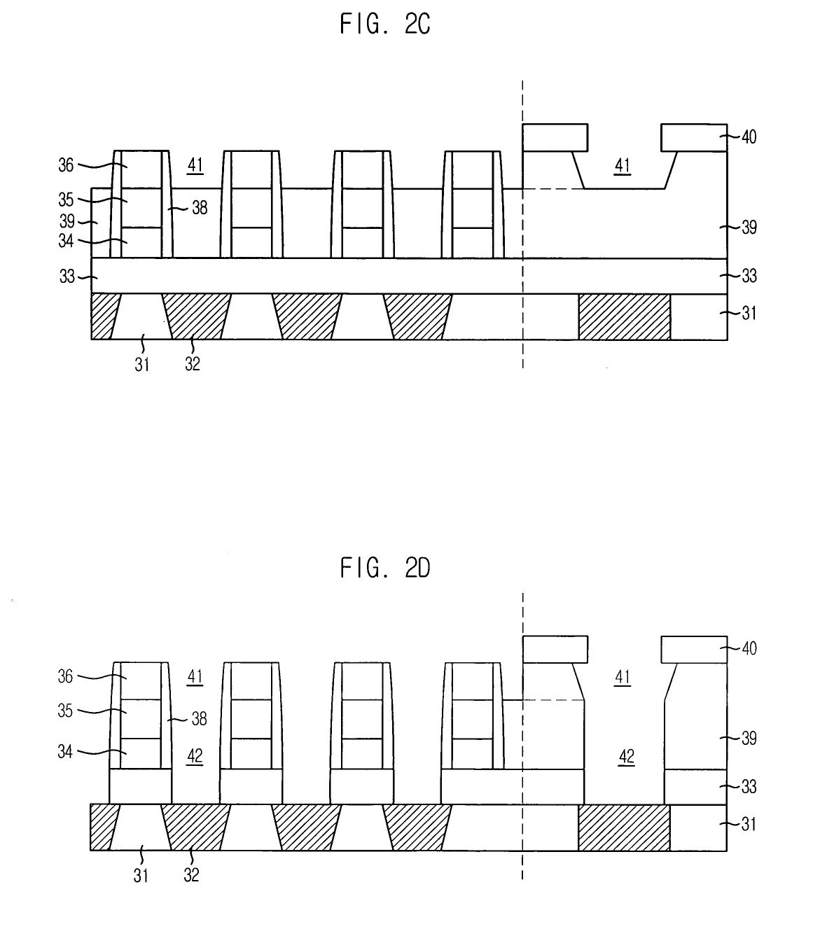

FIGS. 2A to 2E illustrate cross-sectional views to describe a method for fabricating a semiconductor device in accordance with a specific embodiment of the present invention. Each of the cross-sectional views is divided into two sections by a perforated line. A section on the left side of the perforated line shows the cross-sectional view cut across bit line patterns, and a section on the right side of the perforated line shows the cross-sectional view cut parallel to the bit line patterns.

Referring to FIG. 2A, landing plug contacts 32 are formed in a first inter-layer insulation layer 31, and a second inter-layer insulation layer 33 is formed over the landing plug contacts 32 and the first inter-layer insulation layer 31. Bit line patterns are formed over the second inter-layer insulation layer 33. Each of the bit line patterns includes a Ti/TiN layer 34 functioning as a barrier metal, a bit line tungsten layer 35, a nitride-based layer 36, and an amorphous carbon-based layer 37. The nitride-based layer 36 and the amorphous carbon-based layer 37 are included in a double-layer hard mask. In more detail, a double layer structure is formed over the second inter-layer insulation layer 33. The double layer structure includes titanium (Ti) and titanium nitride (TiN) formed in sequential order and functioning as bit line barrier layers. The double layer structure has a thickness ranging from approximately 100 Å to approximately 1,000 Å.

A tungsten layer is formed over the Ti/TiN double layer structure using a chemical vapor deposition (CVD) method. The tungsten layer has a thickness ranging from approximately 300 Å to approximately 1,000 Å. A double-layer hard mask layer is formed over the tungsten layer. The double-layer hard mask layer is formed in a double-layer structure including a preformed nitride-based layer and a preformed amorphous carbon-based layer formed in sequential order. The double-layer hard mask layer has a thickness equivalent to a typical nitride-based bit line hard mask formed in a single layer structure to maintain a gap-fill characteristic during a subsequent third inter-layer insulation layer formation. For instance, the preformed nitride-based layer is formed to have a thickness ranging from approximately 1,000 Å to approximately 2,500 Å, and the preformed amorphous carbon-based layer is formed to have a thickness ranging from approximately 1,000 Å to approximately 2,000 Å.

A bit line patterning process is performed onto the substrate structure. The bit line patterning process includes forming a silicon oxynitride (SiON) layer over the preformed amorphous carbon-based layer and performing a bit line masking and etching process using photoresist. The SiON layer functions as an anti-reflective coating layer, and has a thickness ranging from approximately 300 Å to approximately 1,000 Å. Thus, the bit line patterns are formed, each bit line pattern including the Ti/TiN layer 34, the bit line tungsten layer 35, the nitride-based layer 36, and the amorphous carbon-based layer 37.

During the etching process for forming the bit line patterns, the SiON layer and the double-layer hard mask layer are etched using a gas mixture including methane (CF₄), trifluoromethane (CHF₃), oxygen (O₂), and argon (Ar) at a pressure ranging from approximately 20 mT to approximately 70 mT and applying a power ranging from approximately 300 W to approximately 1,000 W. Also, the tungsten layer and the Ti/TiN double layer structure are etched using a gas mixture including sulfur hexafluoride (SF₆), trichloroborane (BCl₃), nitrogen (N₂), and chlorine (Cl₂) at a pressure ranging from approximately 20 mT to approximately 70 mT and applying a power ranging from approximately 300 W to approximately 1,000 W.

The amorphous carbon-based layers 37 are formed during the bit line pattern formation to increase a top surface area of the bit line patterns. Thus, a polymer may be formed during a subsequent self-aligned contact (SAC) etching process and a SAC etching characteristic may be maintained.

Referring to FIG. 2B, a bit line spacer layer is formed over the substrate structure. The bit line spacer layer includes a nitride-based layer and has a thickness ranging from approximately 50 Å to approximately 150 Å. A bit line spacer etching process is performed thereon to form bit line spacers 38 on both sidewalls of the bit line patterns.

An insulation layer for use as a third inter-layer insulation layer 39 is formed over the substrate structure and filled between the bit line patterns. The insulation layer includes an oxide-based layer formed by employing a high density plasma (HDP) method, and has a thickness ranging from approximately 4,000 Å to approximately 10,000 Å. Thus, a portion of the insulation layer is formed over the bit line patterns with a predetermined thickness while the rest of the insulation layer fills between the bit line patterns.

The insulation layer is planarized by performing an inter-layer dielectric (ILD) chemical mechanical polishing (CMP) process to form the third inter-layer insulation layer 39. The ILD CMP process stops just before the nitride-based layers 36 are polished.

In more detail, portions of the insulation layer and the amorphous carbon-based layers 37 are polished away during the ILD CMP process, exposing top surfaces of the nitride-based layers 36. The third inter-layer insulation layer 39 may be planarized evenly because the amorphous carbon-based layers 37 and the insulation layer including the oxide-based layer are generally polished at substantially the same rate.

Applying the double-layer hard masks may impose a burden on etching during a subsequent storage node contact etching process. The removing of the amorphous carbon-based layers 37 from the double-layer hard masks may decrease such burden.

Referring to FIG. 2C, a KrF photoresist layer is formed over the substrate structure, and photo-exposure and developing processes are performed thereon to form storage node contact masks 40.

The storage node contact masks 40 are line type masks exposing predetermined regions where storage node contact holes are to be formed. The storage node contact masks 40 are formed perpendicular to the bit line patterns.

A storage node contact etching process is performed using the storage node contact masks 40. The storage node contact etching process includes performing a first etching process and a second etching process. The first etching process includes performing a partial etching process. For instance, the first etching process stops before the landing plugs 32 are exposed while etching the third inter-layer insulation layer 39 to expose top surfaces of the landing plug contacts 32. The first etching process is performed to a predetermined depth. The predetermined depth may correspond to a predetermined point in sidewalls on the nitride-based layers 36.

The first etching process, i.e., the partial etching process, includes performing both dry etching and wet etching processes. The dry etching process is performed at a pressure ranging from approximately 15 mT to approximately 50 mT using a power of approximately 1,000 W to approximately 2,000 W and flowing a gas mixture including CF₄, C₄F₈, C₅F₈, C₄F₆, CHF₃, CH₂F₂, Ar, O₂, carbon monoxide (CO), and N₂. The dry etching process is performed to etch a target thickness ranging from approximately 1,000 Å to approximately 2,000 Å, thereby forming openings. The wet etching process is performed using one of a hydrogen fluoride (HF) solution and a buffered oxide etchant (BOE) solution. Sidewalls of the openings are mainly etched during the wet etching process using the HF solution. Thus, the openings formed by the dry etching process become enlarged in a horizontal direction by performing the wet etching process. Consequently, first trenches 41 are formed.

The first etching process for forming the storage node contacts employs the wet etching process after the dry etching process to enlarge the first trenches 41 in a horizontal direction.

The first trenches 41 are formed as a top portion of the storage node contacts holes. Consequently, top portions of storage node contact plugs, which are to be filled in the storage node contact holes, may have an increased open surface area. Thus, an aligning margin may be maintained during a subsequent storage node formation process.

Referring to FIG. 2D, the second etching process of the storage node contact etching process is performed using the storage node contact masks 40 as an etch mask. The first etching process includes performing the partial etching process using both the dry etching process and the wet etching process. However, the second etching process includes etching the inter-layer insulation layers below the first trenches 41 using a dry etching process until the top surfaces of the landing plug contacts 32 are exposed. Thus, second trenches 42 are formed. The dry etching process is performed at a pressure ranging from approximately 15 mT to approximately 50 mT using a power ranging from approximately 1,000 W to approximately 2,000 W and flowing a gas mixture including C₄F₈, C₅F₈, C₄F₆, CH₂F₂, Ar, O₂, CO, and N₂.

The first trenches 41 and the second trenches 42 configure the storage node contact holes. The top portion of the storage node contact holes, i.e., the first trenches 41 enlarged in a horizontal direction, has a line width larger than a bottom portion of the storage node contact holes, i.e., the second trenches 42.

This embodiment does not utilize additional hard masks to form the storage node contact hole, but utilizes only the KrF photoresist. Consequently, the processes may be simplified and costs may be reduced.

Referring to FIG. 2E, the storage node contact masks 40 are stripped, and a cleaning process is performed. A nitride-based layer and a buffer oxide layer are formed over the resultant substrate structure in sequential order. Each of the nitride-based layer and the buffer oxide layer has a thickness ranging from approximately 100 Å to approximately 300 Å. The nitride-based layer may include a silicon nitride layer formed by employing a low pressure chemical vapor deposition (LPCVD) method, and the buffer oxide layer may include an undoped silicate glass (USG) layer.

Subsequently, a spacer etching process is performed using an etch-back process to form storage node contact spacers in a double-layer structure on sidewalls of the storage node contact holes. The storage node contact spacers include nitride-based spacers 43 and buffer oxide spacers 44. The spacer etching process is performed at a pressure ranging from approximately 10 mT to approximately 30 mT using a power ranging from approximately 300 W to approximately 1,000 W and flowing a gas mixture including CF₄, CHF₃, O₂, and Ar.

Consistent with this embodiment, because the buffer oxide layer is formed after the nitride-based layer is formed, a loss of the nitride-based layers 36 may be minimized during the spacer etching process which is performed after forming the storage node contact holes. Furthermore, a typical SAC fail, often caused by asymmetric thicknesses of bit line spacers, may be reduced by forming the nitride-based layer for use as the storage node contact spacers after the storage node contact holes are formed.

A plug polysilicon layer is formed over the substrate structure and filled in the storage node contact holes. The plug polysilicon layer has a thickness ranging from approximately 1,500 Å to approximately 3,000 Å. Then, a storage node contact (SNC) CMP process is performed onto the plug polysilicon layer until the top surfaces of the nitride-based layers 36 are exposed, thereby isolating storage node contact plugs 45.

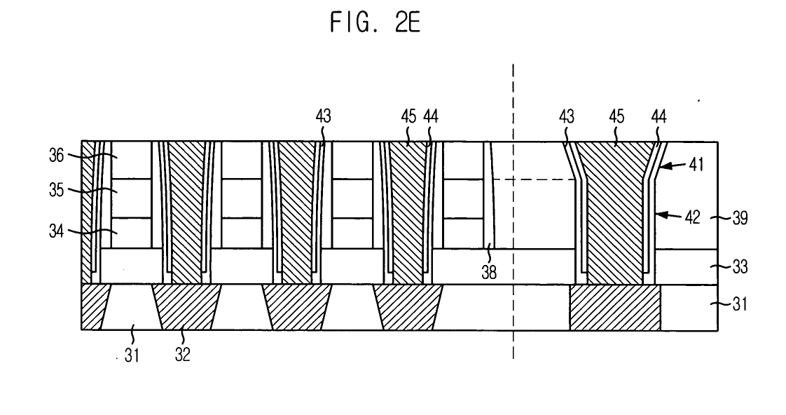

FIG. 3 illustrates a micrographic view of bit line patterns including amorphous carbon-based hard mask layers. As illustrated, a loss of nitride-based bit line hard mask layers is minimized because of the amorphous carbon-based hard mask layers.

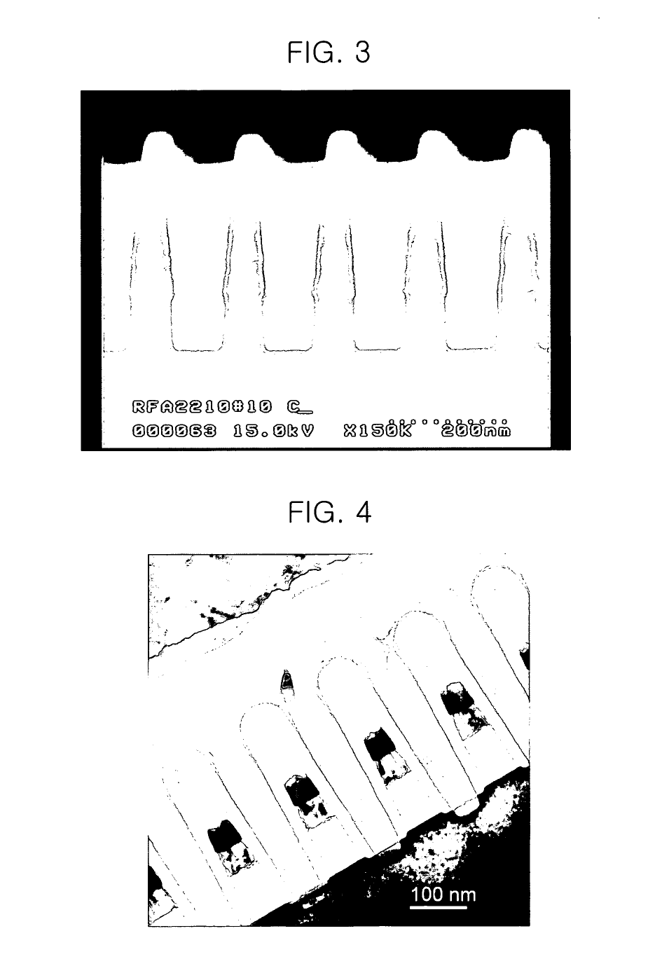

FIG. 4 illustrates a micrographic view of bit line patterns consistent with this embodiment. As shown, a typical SAC fail often caused by asymmetric thicknesses of bit line spacers is reduced.

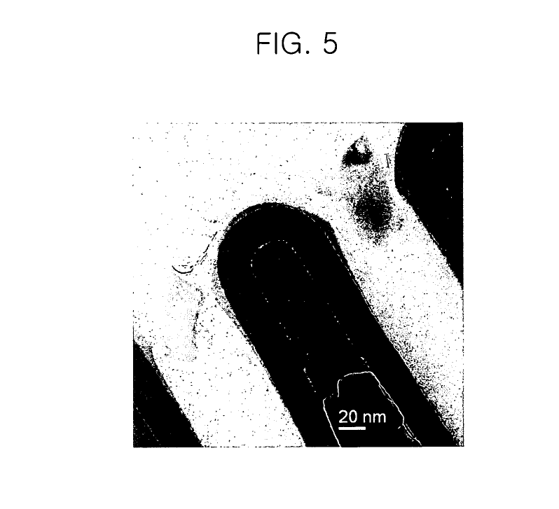

FIG. 5 illustrates a micrographic view of a bit line pattern. A loss of a nitride-based bit line hard mask layer is reduced due to a buffer oxide layer formation.

In accordance with a specific embodiment of the present invention, the loss of the nitride-based bit line hard mask layers can be minimized during the spacer etching process, which is performed after forming the storage node contact holes, by forming the buffer oxide layer.

The storage node contact holes having the enlarged top portions are formed using the line type storage node contact masks, and the storage node contact plugs are formed in the storage node contact holes. Consequently, the open surface area contacting a subsequent storage node is increased. As a result, an overlay margin may be increased with respect to the storage node, and thus, a pad polysilicon layer may not be required.

The line type storage node contact masks are formed using KrF photoresist. Thus, additional storage node contact hard masks are not needed, decreasing costs of production.

Employing the double-layer hard masks allows minimizing the loss of the double-layer hard masks during the storage node contact etching process. Thus, the SAC fail can be reduced.

The present application contains subject matter related to the Korean patent application No. KR 2006-0001836, filed in the Korean Patent Office on Jan. 6, 2006, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a plurality of bit line patterns, each bit line pattern having a double-layer hard mask including a nitride-based layer;
forming a planarized insulation layer filled between the bit line patterns;
forming line type storage node contact masks over predetermined portions of the planarized insulation layer;
etching the planarized insulation layer to form storage node contact holes each having a top portion which is wider than a bottom portion;
forming storage node contact spacers in a double layer structure on sidewalls of the storage node contact holes; and
forming storage node contacts filling the storage node contact holes.

2. The method of claim 1, wherein forming the storage node contact spacers comprises:
forming another nitride-based layer and a buffer oxide layer in sequential order; and
etching the buffer oxide layer and the other nitride-based layer to form the storage node contact spacers in the double layer structure including nitride-based spacers and buffer oxide spacers.

3. The method of claim 2, wherein the other nitride-based layer and the buffer oxide layer each has a thickness ranging from approximately 100 Å to approximately 300 Å.

4. The method of claim 1, wherein etching the planarized insulation layer using the storage node contact masks to form the storage node contact holes comprises:
etching portions of the planarized insulation layer to form first trenches enlarged in a horizontal direction; and
etching other portions of the planarized insulation layer below the first trenches to form second trenches.

5. The method of claim 4, wherein etching the portions of the planarized insulation layer to form the first trenches enlarged in a horizontal direction comprises:
performing a dry etching process onto the portions of the planarized insulation layer using the storage node contact masks as an etch mask to form the first trenches; and
performing a wet etching process to enlarge the first trenches in a horizontal direction.

6. The method of claim 5, wherein performing the dry etching process comprises applying a pressure ranging from approximately 15 mT to approximately 50 mT and a power ranging from approximately 1,000 W to approximately 2,000 W, and flowing a gas mixture including CF₄, C₄F₈, C₅F₈, C₄F₆, CHF₃, CH₂F₂, Ar, O₂, CO, and N₂.

7. The method of claim 6, wherein performing the dry etching process comprises etching the portions of the planarized insulation layer to a thickness ranging from approximately 1,000 Å to approximately 2,000 Å.

8. The method of claim 5, wherein performing the wet etching process comprises using one of hydrogen fluoride (HF) solution and buffered oxide etchant (BOE) solution.

9. The method of claim 4, wherein etching the other portions of the planarized insulation layer below the first trenches to form the second trenches comprises performing a dry etching process.

10. The method of claim 9, wherein performing the dry etching process comprises applying a pressure ranging from approximately 15 mT to approximately 50 mT and a power ranging from approximately 1,000 W to approximately 2,000 W, and flowing a gas mixture including C₄F₈, C₅F₈, C₄F₆, CH₂F₂, Ar, O₂, CO, and N₂.

11. The method of claim 1, wherein forming the planarized insulation layer comprises:
forming an insulation layer over the bit line patterns in a manner to fill the space between the bit line patterns; and
performing a chemical mechanical polishing (CMP) process on the insulation layer, wherein the insulation layer comprises an oxide-based material.

12. The method of claim 11, wherein the double-layer hard mask of each bit line pattern includes an amorphous carbon-based layer and the amorphous carbon-based layers are formed to have a predetermined polishing rate substantially the same as the insulation layer.

13. The method of claim 12, wherein the insulation layer has a thickness ranging from approximately 4,000 Å to approximately 10,000 Å, and the amorphous carbon-based layers have a thickness ranging from approximately 1,000 Å to approximately 2,000 Å.

14. The method of claim 1, wherein the storage node contact masks comprise a KrF-based photoresist material.

15. The method of claim 14, wherein forming the bit line patterns comprises:
forming a barrier metal;
forming a bit line tungsten layer over the barrier metal;
forming a double-layer hard mask layer including a preformed nitride-based layer and a preformed amorphous carbon-based layer over the bit line tungsten layer;
forming an anti-reflective coating layer over the hard mask layer; and
etching the anti-reflective coating layer, the preformed amorphous carbon-based layer, the preformed nitride-based layer, the bit line tungsten layer, and the barrier metal in sequential order.

16. The method of claim 15, wherein the barrier metal comprises a double layer structure including titanium (Ti) and titanium nitride (TiN) formed in sequential order and has a thickness ranging from approximately 100 Å to approximately 1,000 Å.

17. The method of claim 15, wherein the bit line tungsten layer has a thickness ranging from approximately 300 Å to approximately 1,000 Å.

18. The method of claim 15, wherein the preformed nitride-based layer has a thickness ranging from approximately 1,000 Å to approximately 2,500 Å, and the preformed amorphous carbon-based layer has a thickness ranging from approximately 1,000 Å to approximately 2,000 Å.

19. The method of claim 15, wherein etching the preformed amorphous carbon-based layer and the preformed nitride-based layer comprises using a gas mixture including CF₄, CHF₃, O₂, and Ar at a pressure ranging from approximately 20 mT to approximately 70 mT and applying a power ranging from approximately 300 W to approximately 1,000 W.

20. The method of claim 15, wherein etching the bit line tungsten layer and the barrier metal comprises using a gas mixture including SF₆, BCl₃, N₂, and Cl₂ at a pressure ranging from approximately 20 mT to approximately 70 mT and applying a power ranging from approximately 300 W to approximately 1,000 W.

21. The method of claim 1, wherein the planarized insulation layer is flush with the nitride-based layer.
